(19) United States
(12) Patent Application Publication
(10) Pub. No.: US 2007/0222473 A1
(43) Pub. Date: Sep. 27, 2007

(54) Multilayer printed wiring board and method of measuring characteristic impedance

(75) Inventor: Jun Eto, Tokyo (JP)

Correspondence Address: YOUNG & THOMPSON, 745 SOUTH 23RD STREET, 2ND FLOOR, ARLINGTON, VA, 22202, US

(73) Assignee: NEC CORPORATION, Tokyo (JP)

(21) Appl. No.: 11/723,606

(22) Filed: Mar. 21, 2007

(30) Foreign Application Priority Data
Mar. 23, 2006 (JP) 2006-080124

(51) Int. Cl. G01R 31/26

(52) U.S. Cl. 324/765

(57) ABSTRACT

A multilayer printed wiring board having a compact test coupon formed on each of the signal wiring layers is provided, and accurate and efficient method of characteristic impedance measurement for each signal wiring layer is realized. The test coupon is constituted by a plurality of linear parts extending parallel to each other and folded-back parts mutually connecting the linear parts. A through hole is provided for serially connecting the respective test coupons of the signal wiring layers adjoining each other. Two measuring pads, one is connected to one end of the serially connected test coupons and another is connected to the ground layer, are also provided. The measurement is performed by applying a step pulse between two measuring pads and measuring voltages of reflection waves from the serially connected test coupons.

### BACKGROUND OF THE INVENTION

1. Field of the Invention

The present invention relates to a multilayer printed wiring board on which electronic circuit elements are mounted, and to a method of measuring characteristic impedance of signal wirings formed on the multilayer printed wiring board. More particularly, the present invention relates to a technique for measuring characteristic impedance of signal wirings of a multilayer printed wiring board by using a TDR (Time domain Reflectometry) method.

2. Description of the Related Art

In recent years, along with the increase of demand in the density of printed wiring boards, there has been used a multilayer printed wiring board formed by laminating wiring boards, each of which has a wiring pattern formed thereon, in three layers or more including the surface wiring board layer. Further, the operating speed of electronic circuit elements mounted on the multilayer printed wiring board has been more and more increased. In an electronic circuit element operating at high speed, a reflection wave caused by impedance mismatching becomes a cause of generating a trouble in the operation of the electronic circuit element. For this reason, it is required to produce a multilayer printed wiring board with the impedance of wiring patterns, so called pattern impedance, formed on respective signal wiring layers being set within a specified range of value. In order to judge the quality of variations in the pattern impedance value caused by variations in manufacturing the multilayer printed wiring board, a test coupon exclusive for impedance measurement is conventionally provided on each signal wiring layer separately from a wiring pattern. Thus, only a multilayer printed wiring board with a desired impedance value is selected by measuring the test coupon and used as a product.

In a conventional multilayer printed wiring board, a measuring test coupon as shown in FIG. 6 is provided in a free area on a wiring board of a signal wiring layer, or a dedicated test coupon board is formed. Especially in these days, various impedance values exist for each kind of signal, as a result of which a test coupon is generally formed so as to correspond to each signal wiring layer, and is formed so as to include a linear part having a length necessary for the measurement. However, in the case where the test coupon as shown in FIG. 6 is formed, the occupied area of the test coupon becomes large, which often results in a situation where the area required for the test coupon cannot be secured on the wiring board.

In Japanese Patent Laid-Open No. 8-46306, it is described that L-shaped test coupons 61 are arranged at four corners of a printed wiring board 60, as shown in FIG. 7. It is described that the technique described in the patent document makes it possible to easily calculate the characteristic impedance of the test coupon 61 by measuring sectional dimension of a test pattern appearing on the board end face of the L-shaped test coupons provided in the four corners.

In the technique described in the above described patent document, the area of region required for the test coupon is reduced by forming the L-shaped test coupons at four corners of the printed wiring board. However, in this technique, the characteristic impedance of a signal wiring on a printed board is calculated by measuring the cross sectional shape of a wiring formed as the test coupon, and hence, it is difficult to accurately measure the characteristic impedance. The test coupon with the shape shown in FIG. 6 is required to electrically and accurately measure the characteristic impedance, and hence, the occupied area of the test coupon is increased.

Further, at the time of measuring the characteristic impedance by the conventional test coupon as shown in FIG. 6, it is necessary to individually measure the characteristic impedance of respective signal wiring layers by the TDR (Time Domain Reflectmeter) method, and hence, it takes a long time to perform the measurement. For this reason, a method of measuring characteristic impedance which enables the measurement to be efficiently performed is desired.

### SUMMARY OF THE INVENTION

In view of the above described problems of the prior art, it is an object of the present invention to provide a method of measuring characteristic impedance which makes it possible to reduce an area required for forming a test coupon and to accurately and efficiently measure the characteristic impedance, and to provide a multilayer printed wiring board having such test coupon formed thereon.

In order to achieve the above described object, a multilayer printed wiring board according to a first aspect of the present invention, which has a plurality of signal wiring layers and at least one ground layer, is characterized by comprising a test coupon for measuring impedance which is formed on each of the signal wiring layers, through holes which serially connect the test coupons of the respective signal wiring layers, a measuring pad connected to one end of the serially connected test coupons, and another measuring pad connected to the ground layer.

Further, a multilayer printed wiring board according to a second aspect of the present invention, which has a test coupon formed on each signal wiring layer, is characterized in that the test coupon is constituted by a plurality of linear parts extending parallel to each other and folded-back parts which mutually connect the plurality of linear parts.

Further, a method of measuring characteristic impedance according to the present invention, which measures characteristic impedance of a signal wiring of a multilayer printed wiring board having a plurality of signal wiring layers and at least one ground layer, is characterized by comprising forming a test coupon for measuring impedance in each of the signal wiring layers, serially connecting the test coupons of the respective signal wiring layers, applying a step pulse between a measuring pad connected to one end of the serially connected test coupons and another measuring pad connected to the ground layer, and measuring voltages of reflection waves from the serially connected test coupons.

With the multilayer printed wiring board according to the first aspect of the present invention, and the method of measuring characteristic impedance according to the present invention, the test coupons for measuring characteristic impedance of the respective signal wiring layers are serially connected via through holes, which makes it possible to apply a step pulse to the respective test coupons at a time and to thereby efficiently measure the characteristic impedance.

Further, in the multilayer printed wiring board according to the second aspect of the present invention, the test coupon is constituted by a plurality of linear parts extending parallel to each other and folded-back parts connecting the linear parts, which makes it possible to form the test coupon even in a narrow occupied area, and to thereby obtain a multilayer printed wiring board capable of reducing the occupied area of the test coupon.

### BRIEF DESCRIPTION OF THE DRAWINGS

Exemplary features and advantages of the present invention will become apparent from the following detailed description when taken with the accompanying drawings in which:

FIG. 1 is a plan view showing a wiring pattern of a test coupon formed on each signal wiring layer in a multilayer printed wiring board according to an embodiment of the present invention;

FIG. 2 is an exploded perspective view schematically showing the multilayer printed wiring board according to the embodiment of the present invention;

FIG. 3A is a plan view showing details of a corner part of the test coupon shown in FIG. 1;

FIG. 3B is a plan view showing details of measuring pads of the test coupon shown in FIG. 1;

FIG. 4 shows an observation waveform of an oscilloscope measured by the TDR method using a conventional test coupon;

FIG. 5 shows an observation waveform of the oscilloscope measured by the TDR method using the test coupon according to the present embodiment;

FIG. 6 is a plan view showing the conventional test coupon; and

FIG. 7 is a perspective view of the conventional test coupon disclosed in Japanese Patent Laid-Open No. 8-46306.

### DESCRIPTION OF THE EXEMPLARY EMBODIMENTS

In the following, an exemplary embodiment according to the present invention will be described with reference to the accompanying drawings.

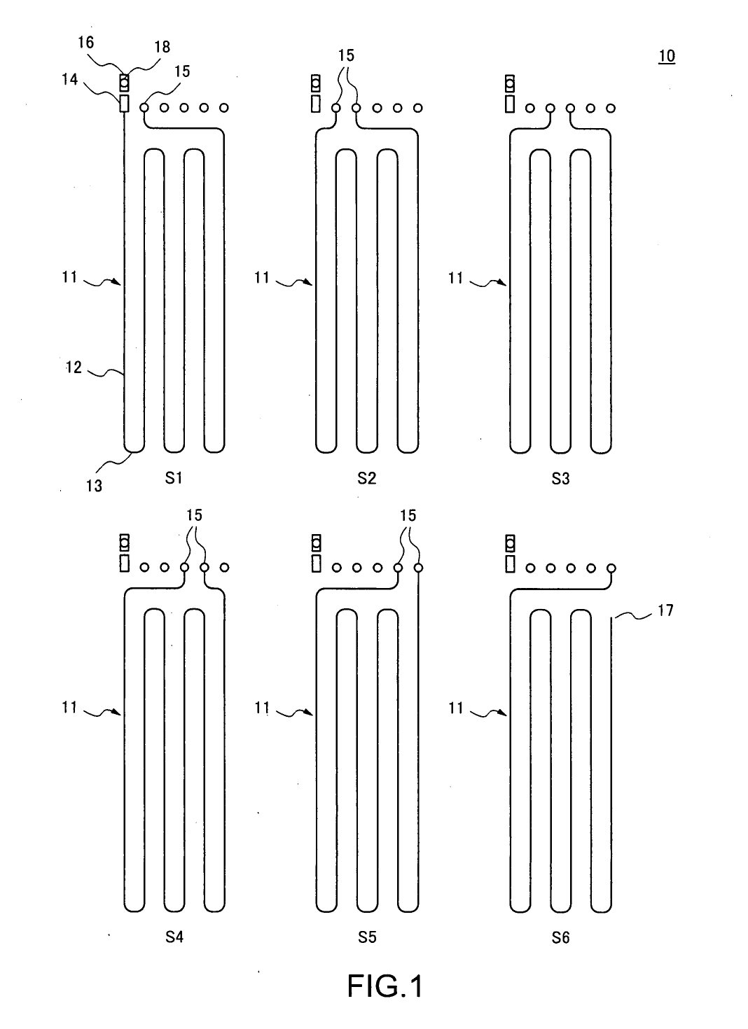

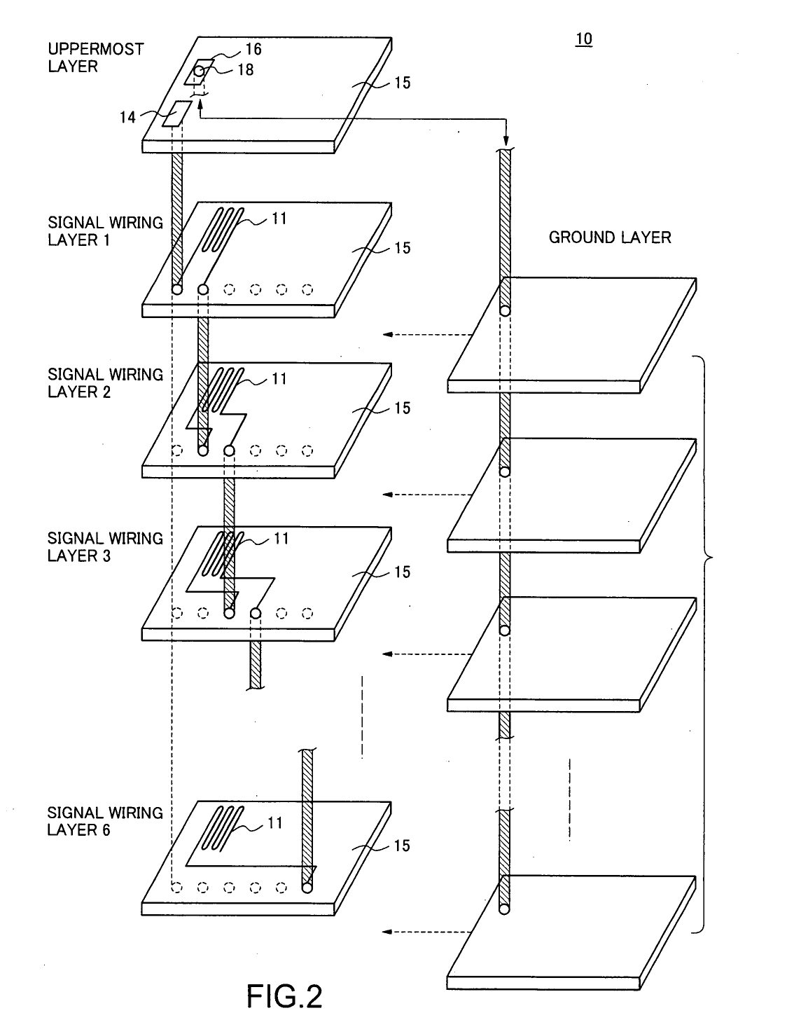

FIG. 1 is a plan view showing a wiring pattern of a test coupon formed on each signal wiring layer in a multilayer printed wiring board 10 according to an embodiment of the present invention. Further, FIG. 2 is an exploded perspective view schematically showing the multilayer printed wiring board 10 according to the embodiment of the present invention.

Each test coupon formed on a multilayer printed wiring board 10 is constituted by an individual test coupon (pattern wiring part) 11 formed on a wiring board of each signal wiring layer, and through holes 15 which mutually connects the pattern wiring parts 11 of the respective signal wiring layers. The pattern wiring part 11 is extended from the connecting part with the through hole 15, and constituted by six linear parts 12 each of which has a width of 0.08 mm to 0.3 mm and a length of about 50 mm, and folded-back parts 13 at which the six linear parts are folded-back so as to be continuously connected. That is, the overall length of the test coupon of each signal wiring layer is about 300 mm. The interval between two adjoining linear parts 12 is 1.27 mm when expressed by a distance between their centers. By securing such center-to-center distance, the effect of inter-wiring stroke can be practically ignored.

One end of the pattern wiring part 11 of the first signal wiring layer (S1) is connected via the through hole to a measuring pad 14 of the uppermost layer (surface wiring board layer) on which the measurement is performed by a probe pin. The other end of the pattern wiring part 11 of the first signal wiring layer is connected via the through hole 15 to one end of the pattern wiring part 11 of the second signal wiring layer (S2). The pattern wiring parts 11 of the respective signal wiring layers (S2 to S6) from the second signal wiring layer to the sixth signal wiring layer are successively connected in series, and the distal end of the pattern wiring part 11 of the sixth signal wiring layer is opened so as to constitute an open end 17. All the ground layers, each of which is sandwiched between two adjoining signal wiring layers, are commonly connected to a measuring pad 16 by a through hole 18.

The measuring pad (probe pad) 14 which constitutes one end of the pattern wiring part 11 of the first signal wiring layer, that is, one end of the whole test coupon, and the measuring pad 16 connected to the ground layer, are exposed side by side on the uppermost layer, respectively, whereby it is possible to measure the characteristic impedance by the TDR method by connecting the probe pin to the measuring pads.

FIG. 2 is an exploded perspective view schematically showing a state where the respective pattern wiring parts 11 described above are serially connected between the adjoining signal wiring layers via the through holes.

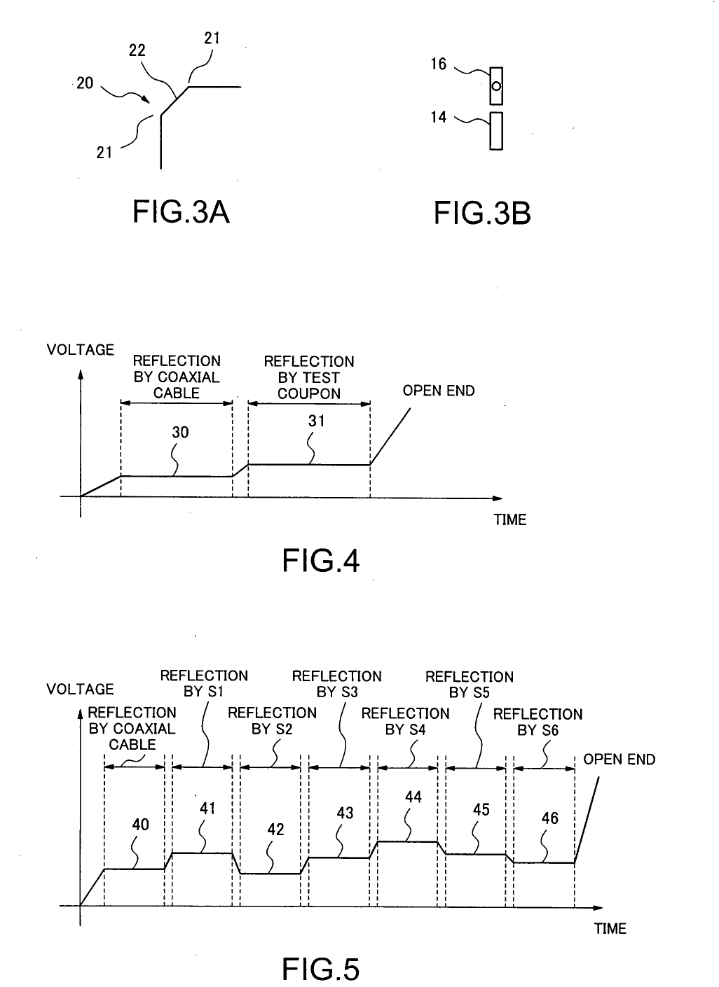

FIG. 3A shows a corner part 20 which constitutes the folded-back part 13 of the pattern wiring part 11, and FIG. 3B shows each constitution of the measuring pads 14 and 16. The corner part 20 has a bending angle of 45° or less at each of the bending part 21. In this example, the bending part is formed so as to have a bending angle of 45° in a position at a distance of 0.3175 mm from the corner of the respective linear parts. Therefore, four bending parts 21 are provided for the folded-back part 13 (two each for respective corner parts). The length of an oblique line 22 of the part sandwiched between the two bending parts 21 is about 0.449 mm.

The two measuring pads 14 and 16 are arranged side by side, and each of the measuring pads 14 and 16 has a rectangular form of 0.9524 mm×2.54 mm. The separation distance between the two measuring pads is 1.27 mm which is equal to the center-to-center distance of the linear parts 12 of the pattern wiring part 11.

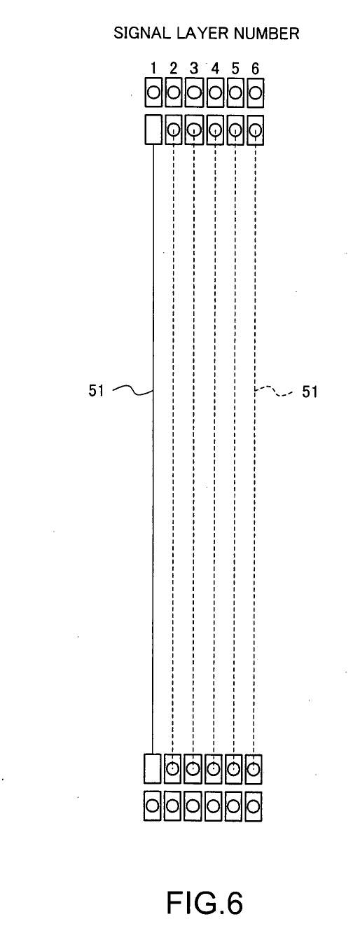

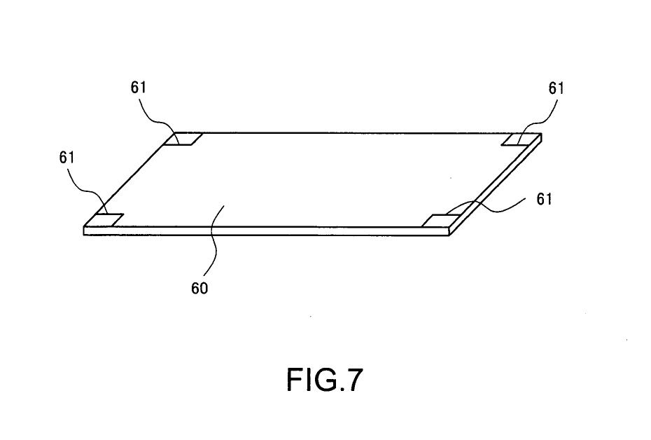

FIG. 4 shows an observation waveform of an oscilloscope measured by the TDR method using a conventional test coupon shown in FIG. 6. The oscilloscope has an internal resistance of 50Ω, and a step pulse of 1V was used for the measurement. In the graph, the time is plotted on the horizontal axis, and the voltage is plotted on the vertical axis. In the TDR measuring method, a step pulse is outputted from a measuring instrument, and applied to one end of the pattern wiring part 51. Then, a reflection wave returning from the other end is observed, and from the observed reflection wave, an impedance of the pattern wiring part 51 is calculated.

In the conventional test coupon, a step pulse of 1 V is applied to each of the pattern wiring parts 51, and a voltage of the reflection wave corresponding to the step pulse is measured. In FIG. 4, a waveform 30 of the reflection wave observed first is a reflection wave by a coaxial cable of the measuring instrument, and the following reflection wave 31 is a reflection wave from the test coupon. The calculation formula of impedance is expressed as follows.

Z0=50×voltage/(1−voltage) (1)

On the basis of this formula (1), the impedance of each of the pattern wiring parts 51 can be calculated from the voltage value in the reflection time region of the pattern wiring part.

FIG. 5 shows an observation waveform of the oscilloscope measured by the TDR method using the test coupon according to the present embodiment. In this measurement, the voltage of reflection waves from all the pattern wiring parts 11 is measured by a single application of the step pulse. The first reflection wave 40 observed after the application of the step pulse is a reflection wave from the coaxial cable of the measuring instrument connected to the measuring probe. The following reflection wave 41 is a reflection wave from the pattern wiring part 11 of the first signal wiring layer. After this reflection wave, reflection waves 42 to 46 from the respective pattern wiring parts 11 of the second signal wiring layer to the sixth signal wiring layer are successively observed.

The propagation delay time from the pattern wiring part 11 of each of the signal wiring layers can be calculated in advance by a theoretical calculation, and hence, the reflection wave from each of the pattern wiring parts 11 can be recognized as it is. For this reason, unlike the conventional test coupon, it is possible to measure the voltage of reflection wave from each of the pattern wiring parts 11 of the plurality of layers by a single application of the step pulse. The voltage value of the recognized reflection wave is measured, and the characteristic impedance is calculated by using the formula (1).

As described above, the pattern wiring part 11 of the respective signal wiring layers is constituted as a zigzag wiring, which makes it possible to reduce the occupied area of the test coupon. In particular, the bending part having a bending angle of 45° or less is formed at the corner part of the wiring pattern, which makes it possible to prevent an unintended signal reflection from occurring at the corner part at the time of measuring the characteristic impedance. For this reason, it is possible to perform accurate impedance measurement. Further, the inter-wiring gap is set to 1.27 mm or more so as to prevent the measurement results from being affected by the interaction between the wirings, as a result of which it is possible to obtain accurate measurement results.

Further, conventionally, each of the signal wiring layers is formed as an independent pattern wiring part, and the measuring pad is formed on each of the independent pattern wiring parts. In the test coupon according to the above described embodiment, the measuring pad is used in common, and wirings for the respective signal wiring layers are mutually connected one by one via the through holes. This makes it possible to reduce the occupied area of the test coupon and to efficiently perform the impedance measurement.

In the above described embodiment, an example in which a pattern wiring part is constituted by a plurality of linear parts and folded-back parts mutually connecting the plurality of linear parts, but the present invention is not limited to the example, provided that the pattern area can be reduced. Further, in the above described embodiment, an example in which through holes are used when the plurality of pattern wiring parts are connected in series, but the present invention is not limited to this example.

As described above, the present invention is explained on the basis of the preferred embodiment thereof, but the multilayer printed wiring board and the measuring method of the characteristic impedance, according to the present invention, are not limited only to the constitution of the above described embodiment, and various modifications and variations of the constitution of the above described embodiment are also included within the scope of the present invention.

The previous description of embodiment is provided to enable a person skilled in the art to make and use the present invention. Moreover, various modifications to this embodiment will be readily apparent to those skilled in the art, and the generic principles and specific examples defined herein may be applied to other embodiments without the use of inventive faculty. Therefore, the present invention is not intended to be limited to the embodiment described herein but is to be accorded the widest scope as define by the limitations of the claims and equivalents.

Further, it is noted that the inventor's intent is to refrain all equivalents of the claimed invention even if the claims are amended during prosecution.

What is claimed is:

1. A multilayer printed wiring board having a plurality of signal wiring layers and at least one ground layer, comprising:
a test coupon for measuring impedance, which is formed on each of the signal wiring layers;
a through hole which serially connects the respective test coupons of the signal wiring layers adjoining each other;
a measuring pad which is connected to one end of the serially connected test coupons; and
a measuring pad which is connected to the ground layer.

2. The multilayer printed wiring board according to claim 1, wherein the test coupon of each of the signal wiring layers is constituted by a plurality of linear parts extending parallel to each other and folded-back parts mutually connecting the plurality of linear parts.

3. The multilayer printed wiring board according to claim 2, wherein the folded-back part is constituted by a plurality of bending parts, and a bending angle of each of the bending parts is 45° or less.

4. A method of measuring characteristic impedance of a plurality of signal wiring layers of a multilayer printed wiring board having the plurality of signal wiring layers and at least one ground layer, comprising:
forming a test coupon for measuring impedance on each of the signal wiring layers;
serially connecting the test coupons of the respective signal wiring layers;
applying a step pulse between a measuring pad connected to one end of the serially connected test coupons and a measuring pad connected to the ground layer; and
measuring voltages of reflection waves from the serially connected test coupons.

5. The method of measuring characteristic impedance according to claim 4, wherein the test coupon of each of the signal wiring layers is constituted by a plurality of linear parts extending parallel to each other and folded-back parts mutually connecting the plurality of linear parts.

6. The method of measuring characteristic impedance according to claim 5, wherein the folded-back part is constituted by a plurality of bending parts, and a bending angle of each of the bending parts is 45° or less.

7. A multilayer printed wiring board in which a test coupon is formed in a signal wiring layer,
wherein the test coupon is constituted by a plurality of linear parts extending parallel to each other and folded-back parts mutually connecting the plurality of linear parts.

8. The multilayer printed wiring board according to claim 7, wherein the folded-back part is constituted by a plurality of bending parts, and a bending angle of each of the bending parts is 45° or less.
